(19) United States
(12) Patent Application Publication
(10) Pub. No.: US 2011/0120652 A1
(43) Pub. Date: May 26, 2011

(54) PLASMA GENERATING APPARATUS

(75) Inventors: Chia-Hao CHANG, Nantou County (TW); Chih-Chen Chang, Banciao City (TW)

(73) Assignee: INDUSTRIAL TECHNOLOGY RESEARCH INSTITUTE, Hsinchu (TW)

(21) Appl. No.: 12/788,254

(22) Filed: May 26, 2010

(30) Foreign Application Priority Data
Nov. 25, 2009 (TW) 98140218

(51) Int. Cl. H01L 21/3065

(52) U.S. Cl. 156/345.48; 118/723 E

(57) ABSTRACT

A plasma generating apparatus is provided. The plasma generating apparatus includes a plasma process chamber, a top electrode board, a bottom electrode board and at least one pair of impedance modulators. The top electrode board is coupled to a radio frequency (RF) power source. The impedance modulators are provided in pairs and are parallel-connected to the top electrode board at two geometrically symmetrical locations, wherein each impedance modulator has an impedance modulation curve whose value changes with time, and the value of a parallel equivalent impedance curve of the impedance modulation curves is constant with time.

This application claims the foreign priority benefit of Taiwan application Serial No. 098140218, filed Nov. 25, 2009, the subject matter of which is incorporated herein by reference.

### BACKGROUND OF THE INVENTION

1. Technical Field

The disclosure relates in general to a plasma generating apparatus, and more particularly to a plasma generating apparatus generating plasma by a radio frequency (RF) wave.

2. Description of the Related Art

A plasma generating apparatus can perform thin film deposition or etching during the manufacturing process of some products such as thin film solar cells, liquid crystal displays and semiconductor wafers, and is therefore a critical apparatus in such manufacturing. However, if the size of the top electrode board of the plasma generating apparatus is close to the wavelength radio frequency (RF) waves, a standing RF wave will be generated. A standing wave will result in a non-uniform distribution of plasma, and therefore produce non-uniform plating or etching. Particularly, when the frequency of the RF wave increases, the standing wave effect becomes even stronger.

### SUMMARY OF THE INVENTION

The disclosure is directed to a plasma generating apparatus, which modulates the plasma by means of more than one pair of impedance modulators, so that the standing wave node generated by the radio frequency (RF) wave moves continuously, so as to generate a uniform distribution of plasma over time.

According to a first aspect of the disclosure, a plasma generating apparatus includes a plasma process chamber, a top electrode board, a bottom electrode board and at least two impedance modulators. The top electrode board is coupled to a radio frequency (RF) power source. The impedance modulators are provided in pairs and are parallel-connected to the top electrode board at two geometrically symmetrical locations, wherein each impedance modulator has an impedance modulation curve whose value changes with time, and the value of a parallel equivalent impedance curve of the impedance modulation curves is constant with time.

The disclosure will become apparent from the following detailed description of the preferred but non-limiting embodiments. The following description is made with reference to the accompanying drawings.

### BRIEF DESCRIPTION OF THE DRAWINGS

The disclosure can be more fully understand by reading the subsequent detailed description and examples with references made to the accompanying drawings, wherein

FIG. 1 is a schematic view of a plasma generating apparatus according to a first embodiment of the disclosure;

FIG. 2 is a schematic top view of a top electrode board, first and second impedance modulators of FIG. 1;

FIG. 3A is a graph showing first and second impedance modulation curves according to the first embodiment of the disclosure;

FIG. 3B is a schematic view of a graph showing the parallel equivalent impedance curve of the first and second impedance modulators according to the first embodiment of the disclosure;

FIG. 4 is a schematic top view of the top electrode board and first to fourth impedance modulators of a plasma generating apparatus according to a second embodiment of the disclosure;

FIG. 5 is a schematic top view of the top electrode board and first to fourth impedance modulators of another plasma generating apparatus according to the second embodiment of the disclosure;

FIG. 6A is a schematic view of a graph showing first to fourth impedance modulation curves according to the second embodiment of the disclosure;

FIG. 6B is a schematic view of a graph showing the parallel equivalent impedance curve of the first to fourth impedance modulators according to the second embodiment of the disclosure;

FIG. 7 is a schematic top view of the top electrode board and first to eighth impedance modulators of a plasma generating apparatus according to a third embodiment of the disclosure;

FIG. 8A is a schematic view of a graph showing first to eighth impedance modulation curves according to the third embodiment of the disclosure; and

FIG. 8B is a schematic view of a graph showing a parallel equivalent impedance curve of first to eighth impedance modulators according to the third embodiment of the disclosure.

### DETAILED DESCRIPTION OF THE INVENTION

In the following detailed description, for purpose of explanation, numerous specific details are set forth in order to provide a through understanding of the disclosed embodiments. It will be apparent, however, that one or more embodiments may be practiced without these specific details. In other instances, well-known structures and devices are schematically shown in order to simplify the drawing.

A number of embodiments are described below for elaborating upon the disclosure only and not as a limitation upon the scope of the disclosure. Besides, some elements are omitted in the following embodiment to highlight the technical features of the disclosure.

### First Embodiment

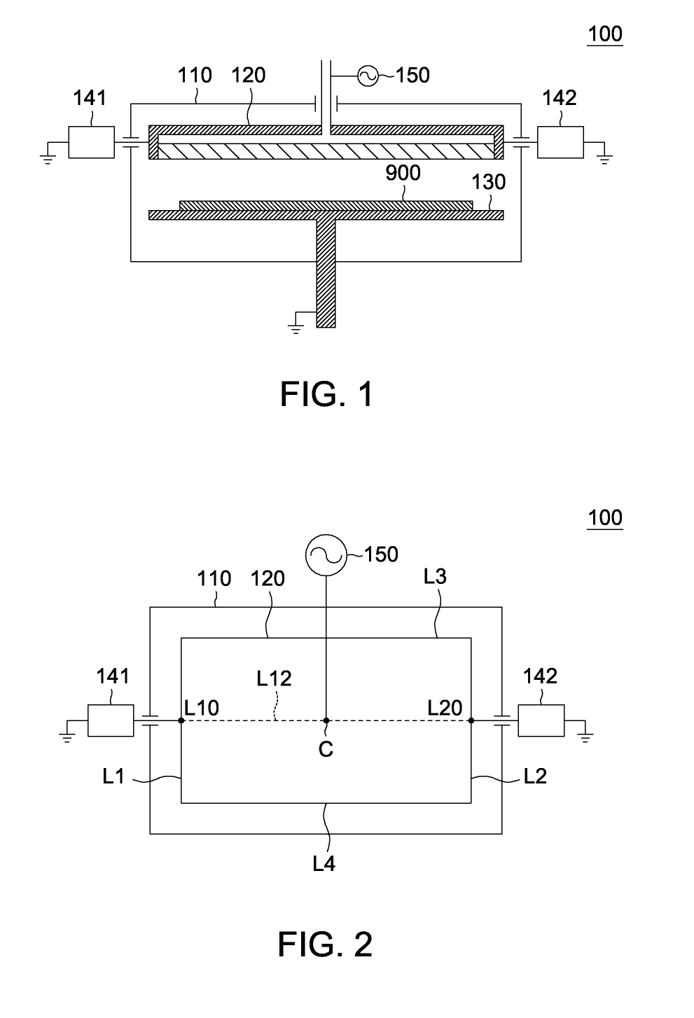

Referring to FIG. 1, plasma generating apparatus 100 includes a plasma process chamber 110, a top electrode board 120, a bottom electrode board 130, a first impedance modulator 141, a second impedance modulator 142, an RF power source 150, a vent hole and a vacuum pump (the vent hole and the vacuum pump are not illustrated in FIG. 1). The top electrode board 120 and the bottom electrode board 130 are disposed in parallel on top and bottom sides of the plasma process chamber 110. The top electrode board 120 is connected to the RF power source 150. Normally, the RF power source 150 is applied to the top electrode board 120, and the bottom electrode board 130 can be directly grounded or float. During manufacture, a gas is infused into the plasma process chamber 110 from the gas injection port (not illustrated in FIG. 1). When the RF power source 150 outputs sufficient RF power, a plasma is generated and maintained between the top electrode board 120 and the bottom electrode board 130. During the manufacturing process, the substrate 900 (such as a to-be-processed semiconductor wafer or a glass substrate that can be processed into a display panel or solar cell board) is placed on the bottom electrode board 130, and various manufacturing processes are performed upon the substrate 900 through the plasma. The vacuum pump withdraws reacted gas through the vent hole. The first impedance modulator 141 and the second impedance modulator 142 are placed on the two sides of the top electrode board 120 or the bottom electrode board 130 at geometrically symmetric locations (FIG. 1 shows an embodiment in which the first impedance modulator 141 and the second impedance modulator 142 are placed on the top electrode board 120). The first impedance modulator 141 and the second impedance modulator 142 both are tunable capacitors.

Referring to FIG. 2, the top electrode board 120 can be a rectangular structure or a circular structure. In the present embodiment, the top electrode board 120 is a rectangular structure. The top electrode board 120 has a first lateral side L1, a second lateral side L2, a third lateral side L3 and a fourth lateral side L4. As shown in FIG. 2, the connected line L12 between the first impedance modulator 141 and the second impedance modulator 142 passes through the center C of the top electrode board 120. In this embodiment, the first impedance modulator 141 and the second impedance modulator 142 are electrically connected to the middle point L10 of the first lateral side L1 and the middle point L20 of the second lateral side L2, respectively.

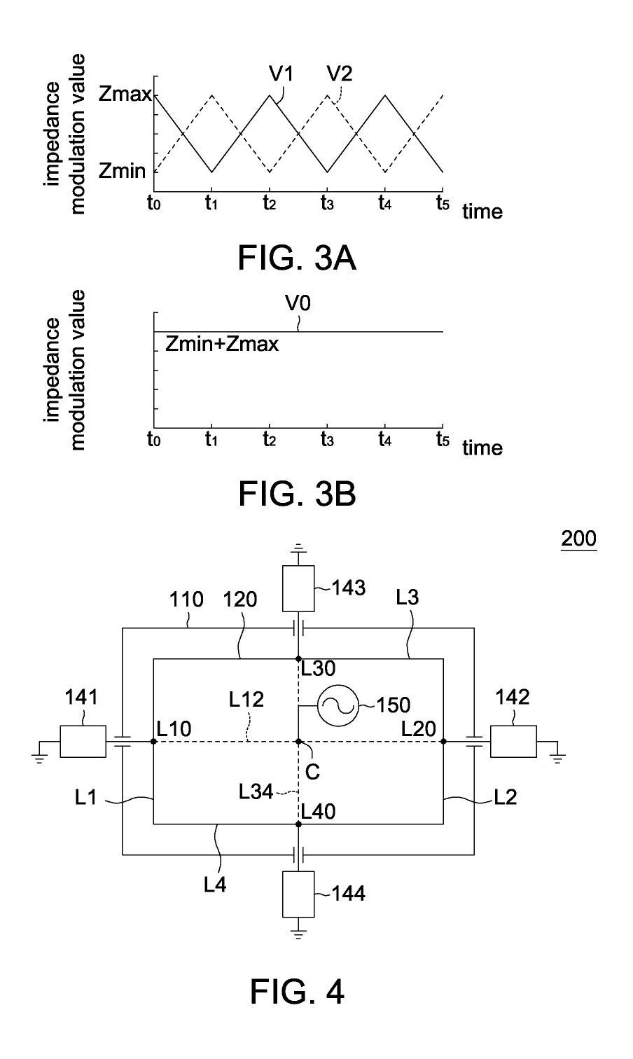

Referring to FIG. 3A, the first impedance modulator 141 has a first impedance modulation curve V1 whose value changes with time, and the second impedance modulator 142 has a second impedance modulation curve V2 whose value changes with time.

Let FIG. 3A be taken for example. Within the time interval of the time points t0 to t5, in succession the value of the first impedance modulation curve V1 linearly decreases from the maximum impedance modulation value Zmax to the minimum impedance modulation value Zmin, linearly increases back to Zmax, again linearly decreases to Zmin, and so on. To the contrary, during the same time interval the value of the second impedance modulation curve V2 linearly increases from Zmin Zmax, linearly decreases to Zmin, again linearly increases to Zmax, and so on. Thus, within the same time interval, while the value of the first impedance modulation curve V1 decreases, the value of the second impedance modulation curve V2 is increasing, and while the value of the first impedance modulation curve V1 increases, the value of the second impedance modulation curve V2 is decreasing.

As a result, the standing wave nodes generated in the plasma by the RF waves continuously moves, so as to generate a plasma whose average density over time is the same throughout, which is the purpose of the impedance modulation. The appropriate rate of the impedance modulation to achieve optimization of the manufacturing process will depend on various factors, but as the rate of modulation increases the overall uniformity of the plasma becomes greater. Normally, the rate of modulation would be in the range of 0.1 Hz to 1000 Hz.

As indicated in FIG. 3A, the maximum impedance modulation value Zmax of the first impedance modulation curve V1 substantially is equal to the maximum impedance modulation value Zmax of the second impedance modulation curve V2, and the minimum impedance modulation value Zmin of the first impedance modulation curve V1 substantially is equal to the minimum impedance modulation value Zmin of the second impedance modulation curve V2. As indicated in FIG. 3B, under the circumstances that the changes in the first impedance modulation curve V1 and the second impedance modulation curve V2 are exactly opposite and complementary to each other, the value of the parallel equivalent impedance curve V0 at any time point is identical (=Zmin+Zmax). Thus, the overall plasma source impedance will remain constant, and the transmission of the RF power maintains the plasma strength stable and will not be affected by tuning of the first and second impedance modulator 141 and 142 during the plating or etching process.

### Second Embodiment

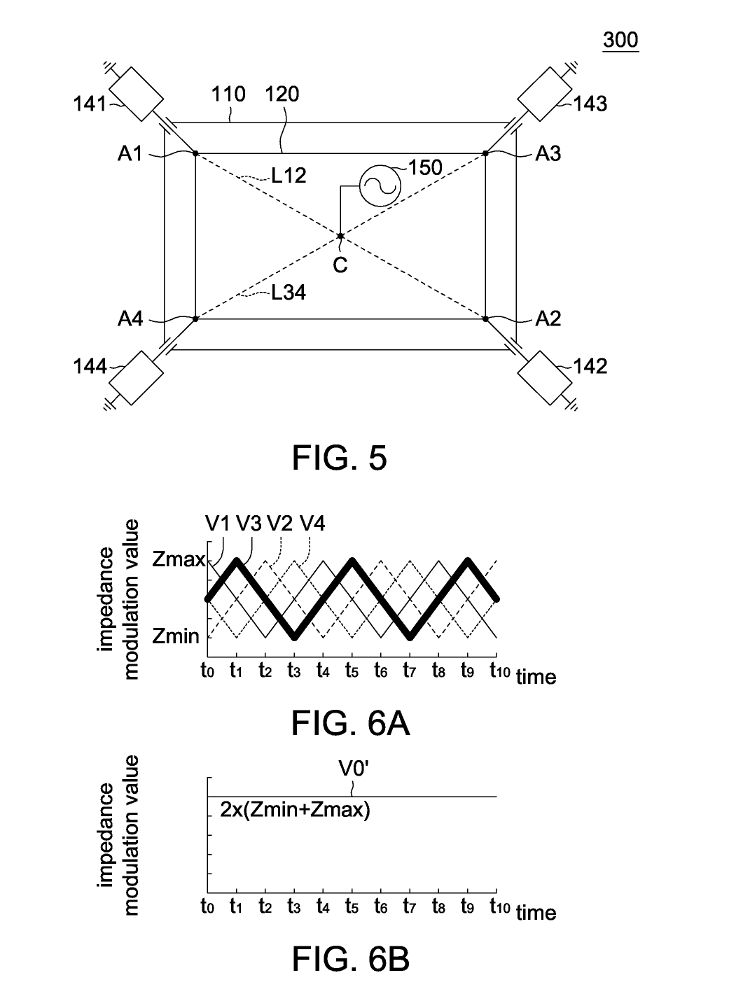

Referring to FIG. 4 and FIG. 5, plasma generating apparatuses 200 and 300 of the embodiment of the disclosure differs with the plasma generating apparatus 100 of the first embodiment in the quantity of the impedance modulators, and other similarities are not repeated here. As indicated in FIGS. 4 and 5, the plasma generating apparatus 200 of the present embodiment of the disclosure further includes a third impedance modulators 143 and a fourth impedance modulator 144 in pair in addition to the first impedance modulator 141 and the second impedance modulator 142 in pair.

In the first embodiment, the connected line L12 of the first impedance modulator 141 and the second impedance modulator 142 passes through the center C of the top electrode board 120. Likewise, the connected line L34 of the third impedance modulators 143 and the fourth impedance modulator 144 also passes through the center C of the top electrode board 120. Thus, the first to fourth impedance modulators 141 to 144 are disposed at several geometrically symmetrical locations.

Let the plasma generating apparatus 200 of FIG. 4 be taken for example. When the first impedance modulator 141 and the second impedance modulator 142 are electrically connected to the middle point L10 of the first lateral side L1 and the middle point L20 of the second lateral side L2 respectively, the third impedance modulator 143 and the fourth impedance modulator 144 are electrically connected to the middle point L30 of the third lateral side L3 and the middle point L40 of the fourth lateral side L4 respectively.

Let the plasma generating apparatus 300 of FIG. 5 be taken for example. When the first impedance modulator 141 and the second impedance modulator 142 are electrically connected to the first corner point A1 and the second corner point A2 respectively, the third impedance modulator 143 and the fourth impedance modulator 144 are electrically connected to the third corner point A3 and the fourth corner point A4 respectively. Thus, the first to fourth impedance modulators 141 to 144 are disposed at several geometrically symmetrical locations.

Referring to FIG. 6A, the first impedance modulator 141, the second impedance modulator 142, the third impedance modulator 143 and the fourth impedance modulator 144 respectively have the first impedance modulation curve V1, the second impedance modulation curve V2, the third impedance modulation curve V3 and the fourth impedance modulation curve V4 whose value change with time.

Let FIG. 6A be taken for example. Within the same time interval, while the value of the first impedance modulation curve V1 progressively decreases, the value of the second impedance modulation curve V2 is progressively increasing, and while the value of the first impedance modulation curve V1 progressively increases, the value of the second impedance modulation curve V2 progressively is decreasing. While the value of the third impedance modulation curve V3 progressively decreases, the value of the fourth impedance modulation curve V4 progressively is increasing, and while the value of the third impedance modulation curve V3 progressively increases, the value of the fourth impedance modulation curve V4 progressively is decreasing. Wherein, the third impedance modulation curve V3 differs with the first impedance modulation curve V1 by ¼ period phase.

Through repetitive periodical change, the standing wave node generated by the RF electromagnetic wave is periodically moved with time, so as to generate a plasma whose average density over time is the same through, which is the purpose of the impedance modulation. The appropriate rate of the impedance modulation to achieve the optimization of the manufacturing process will depend on various factors, but as the rate of modulation increases the overall uniformity of the plasma becomes greater. Normally, the rate of modulation would be in the range of 0.1 Hz to 1000 Hz.

As indicated in FIG. 6A, the maximum impedance modulation values Zmax of the first impedance modulation curve V1, the second impedance modulation curve V2, the third impedance modulation curve V3 and the fourth impedance modulation curve V4 are identical, and so are the minimum impedance modulation values Zmin of the first impedance modulation curve V1, the second impedance modulation curve V2, the third impedance modulation curve V3 and the fourth impedance modulation curve V4 identical. As indicated in FIG. 6B, under the circumstances that the changes of the value of the first impedance modulation curve V1 and the second impedance modulation curve V2 are exactly opposite and complementary to each other, and so are the changes of the value of the third impedance modulation curve V3 and the fourth impedance modulation curve V4 exactly opposite and complementary to each other, the value of the parallel equivalent impedance curve V0′ at any time point is identical (=2×[Zmin+Zmax]). Thus, the overall plasma source impedance will remain constant, and the transmission of the RF power maintains the plasma strength stable and will not be affected by tuning of the first to fourth impedance modulators 141 to 144 during the plating or etching process.

### Third Embodiment

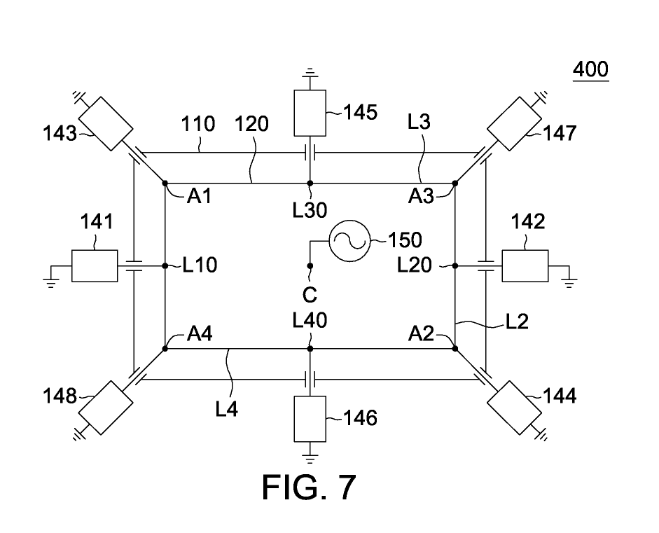

Referring to FIG. 7, plasma generating apparatus 400 of the present embodiment of the disclosure differs with the plasma generating apparatus 100 of the first embodiment in the quantity of the impedance modulators, and the similarities are not repeated here. As indicated in FIG. 7, the plasma generating apparatus 400 of the embodiment of the disclosure further includes a third impedance modulator 143 and a fourth impedance modulator 144 in pair, a fifth impedance modulator 145 and a six impedance modulator in pair 146 in pair, and a seventh impedance modulator 147 and a eighth impedance modulator 148 in pair in addition to the first impedance modulator 141 and the second impedance modulator 142 in pair. The first to eighth impedance modulators 141 to 148 are respectively parallel-connected to the middle point L10 of the first lateral side L1, the middle point L20 of the second lateral side L2, the first corner point A1, the second corner point A2, the middle point L30 of the third lateral side L3, the middle point L40 of the fourth lateral side L4, the third corner point A3 and the fourth corner point A4 as of the top electrode board 120.

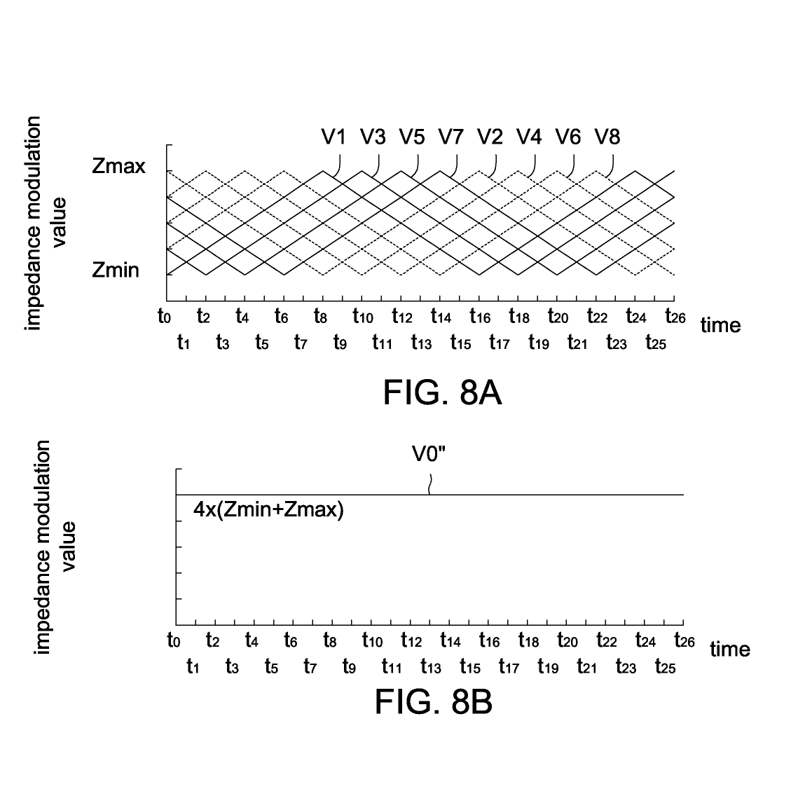

Referring to FIG. 8A, the first to eighth impedance modulators 141 to 148 respectively have first to eighth impedance modulation curves V1 to V8 whose value change with time.

Let FIG. 8A be taken for example. Within the same time interval, the changes of the value of the first impedance modulation curve V1 and the second impedance modulation curve V2 are exactly opposite and complementary to each other, and so are the changes of the value of the third impedance modulation curve V3 and the fourth impedance modulation curve V4, the changes of the value of the fifth impedance modulation curve V5 and the six impedance modulation curve V6, and the changes of the value of the seventh impedance modulation curve V7 and the eighth impedance modulation curve V8 exactly opposite and complementary to each other.

Moreover, the third impedance modulation curve V3 differs the first impedance modulation curve V1 by ⅛ period phase, the fifth impedance modulation curve V5 differs the third impedance modulation curve V3 by ⅛ period phase, and the seventh impedance modulation curve V7 differs the fifth impedance modulation curve V5 by ⅛ period phase.

Through repetitive periodical change, the standing wave node generated by the RF electromagnetic wave is periodically moved with time, so as to generate a plasma whose average density over time is the same through, which is the purpose of the impedance modulation. The appropriate rate of the impedance modulation to achieve the optimization of the manufacturing process will depend on various factors, but as the rate of modulation increases the overall uniformity of the plasma becomes greater. Normally, the rate of modulation would be in the range of 0.1 Hz to 1000 Hz. Normally, the rate of modulation would be in the range of 0.1 Hz to 1000 Hz.

Referring to FIG. 8B, the value of a parallel equivalent impedance curve V0″ at any time point is identical (=4×[Zmin+Zmax]). Thus, the overall plasma source impedance will remain constant with time, and the transmission of the RF power maintains the plasma strength stable and will not be affected by tuning of the first to eighth impedance modulators 141 to 148 during the plating or etching process.

The plasma generating apparatus described the above embodiments of the disclosure modulates the plasma by one or more than one set of impedance modulators, so that the standing wave node generated by the RF wave is moved with time, so as to generate a plasma whose average density over time is the same through and meets the uniformity requirement in the manufacturing process of plasma.

While the disclosure has been described by way of example and in terms of several embodiments, it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A plasma generating apparatus, comprising:
a plasma process chamber;
a top electrode coupled to a radio frequency (RF) power source;
a bottom electrode; and
at least two impedance modulators, wherein the impedance modulators are provided in pairs and are parallel-connected to the top electrode board at two geometrically symmetrical locations, wherein each impedance modulator has an impedance modulation curve whose value changes with time, and the value of a parallel equivalent impedance curve of the impedance modulation curves is constant with time.

2. The plasma generating apparatus according to claim 1, wherein the changes of the value of the paired impedance modulation curves are opposite and complementary to each other.

3. The plasma generating apparatus according to claim 1, wherein the value of each impedance modulation curve is linearly increasing or linearly decreasing.

4. The plasma generating apparatus according to claim 1, wherein the maximum value of each impedance modulation curve is substantially identical.

5. The plasma generating apparatus according to claim 1, wherein the minimum value of each impedance modulation curve is substantially identical.

6. The plasma generating apparatus according to claim 1, wherein the top electrode is a rectangular structure or a circular structure.

7. The plasma generating apparatus according to claim 1, wherein the connected line of the paired impedance modulators passes through the center of the top electrode.

8. The plasma generating apparatus according to claim 1, wherein the paired impedance modulators respectively are electrically connected to the middle points of two opposite lateral sides of the top electrode.

9. The plasma generating apparatus according to claim 1, wherein the paired impedance modulators respectively are electrically connected to two opposite corner points of the top electrode.

10. The plasma generating apparatus according to claim 1, wherein the impedance modulators both are tunable.
